(19) United States
(12) Patent Application Publication
(10) Pub. No.: US 2014/0216531 A1
(43) Pub. Date: Aug. 7, 2014

(54) Solar Panel Assembly

(71) Applicant: Magna International Inc., Aurora (CA)

(72) Inventor: Mark F. Werner, LaSalle (CA)

(21) Appl. No.: 14/345,765

(22) PCT Filed: Sep. 20, 2012
(86) PCT No.: PCT/CA2012/000872

§ 371 Date: Mar. 19, 2014

Related U.S. Application Data
(60) Provisional application No. 61/537,610, filed on Sep. 22, 2011.

(51) Int. Cl. H01L 31/042

(52) U.S. Cl. CPC H01L 31/0422
USPC 136/251

(57) ABSTRACT

A solar assembly for harnessing solar rays and generating electricity is provided. The solar assembly includes a mounting structure with a pair of sub-assemblies spaced from one another in an east-west direction and each having at least one post and a north-south rail. A plurality of east-west rails extend between the north-south rails of adjacent sub-assemblies. A plurality of photovoltaic (PV) arrays are attached to the east-west rails. The north-south rails of the sub-assemblies are curved concave downwardly towards the base such that the PV arrays are disposed at different angles from one another with the upper-most array being disposed at the shallowest angle relative to the base and the lower-most array being disposed at the steepest angle relative to the base.

### CROSS-REFERENCE TO PRIOR APPLICATION

This U.S. National Stage Patent Application claims priority to International Application No. PCT/CA2012/000872 filed Sep. 20, 2012 which claims the benefit of U.S. Provisional Patent Application Ser. No. 61/537,610 filed Sep. 22, 2011, entitled “Solar Panel Assembly,” the entire disclosures of the applications being considered part of the disclosure of this application and hereby incorporated by reference.

### BACKGROUND OF THE INVENTION

1. Field of the Invention

The subject invention is related to a solar panel assembly, and more precisely to a solar panel assembly including a mounting structure for solar panels.

2. Description of the Prior Art

Solar power is becoming an increasingly popular alternative to fossil fuels for generating electricity. In general, solar power generators harness the potential energy of solar radiation and convert that potential energy into electricity. Some solar power generators utilize an array of minors which reflect and concentrate light into a small area. Heat from the reflected and concentrated light is then used to generate electricity in a manner similar to conventional power plants. Another type of solar power generator is a photovoltaic (PV) cell, which harnesses solar rays and directly converts solar radiation into electricity.

PV cells are typically arranged in an array on a solar panel and are supported by a mounting structure. For maximum effectiveness, the PV arrays must remain outdoors, and therefore, the PV arrays and mounting structure must be resistant to a wide range of environmental factors including, for example, high winds, rain, hail, large snow falls and seismic loads. Some mounting structures are designed as trackers to automatically reorient the PV arrays to “follow the sun” as it moves through the sky, thereby maximizing the solar rays harnessed. However, such mounting structures may not always be cost-effective. Therefore, most PV panels are mounted on a stationary mounting structure which orients the PV panels at a predetermined angle. However, due to seasonal changes of the earth's axis relative to the sun, the optimal angle at which the PV panel should be operated changes continuously. Accordingly, a large amount of potential energy is inherently lost by the stationary PV panels. The amount of potential energy that is lost increases with increasing distance from the equator.

One known type of mounting structure is generally shown in FIG. 1. The structure includes a pair of vertical posts, or legs, spaced from one another and a linear north-south rail extending between the legs for supporting the PV panels. In this embodiment, the north-south rail is angled at twenty-eight degrees (28°) relative to the ground. The angle of the north-south rail, and thus that of the PV arrays, can only be changed manually, which is often a laborious and time-consuming process.

There remains a significant and continuing need for a stationary mounting structure which is cost effective, is resistant to outdoor environmental forces and increases the amount of solar rays harnessed by the PV arrays throughout the year.

### SUMMARY OF THE INVENTION

One aspect of the present invention provides for a solar assembly for harnessing solar rays and generating electricity. The solar assembly includes at least two posts extending vertically upwardly from a base and spaced from one another. The solar assembly also includes at least two north-south rails, each of which is coupled to an upper end of one of the posts with the north-south rails extending in generally parallel relationship with one another. A plurality of generally flat solar arrays are coupled to the east-west rails, and the north-south rail is curved concave downwardly such that the solar arrays are oriented at different angles relative to the base and relative to one another. This aspect of the solar assembly is advantageous because it produces an increased amount of power during the winter season, particularly in geographical locations far from the equator where the sun does not rise as high in the sky. This increased power is a result of the steeply angled lower solar arrays receiving more sun rays than the shallow angled upper solar arrays during the winter when the sun is low in the sky. Conversely, during the summer months there is increased power as a result of the shallower angled upper solar arrays receiving an increased amount of solar rays when the sun is high in the sky.

Additionally, this aspect the present invention is advantageous because the curved north-south member provides the solar assembly with a more aerodynamic profile. With the more aerodynamic profile, the magnitude of the forces exerted on the mounting structure during windy days is reduced. Thus, the components of the mounting structure may be formed of lighter, cheaper materials without compromising its ability to resist wind forces on windy days.

Even further, the curved north-south rail provides greater strength and stiffness properties to the mounting structure than would a linear north-south rail since an arch design transmits some load to the posts through compression whereas linear beams transmit load through bending stresses. Accordingly, the mounting structure may be formed of a lighter, cheaper material without compromising its ability to support the solar arrays or resist forces that it will likely encounter in everyday outdoor use including, for example, wind, snow loads, ice loads, rain loads or seismic loads.

Moreover, curved north-south rail assists in removing snow or ice from the steeply angled bottom PV arrays which reduces the risk of the PV arrays being obstructed by snow or ice, which can obstruct sun rays. This is because precipitation automatically falls off of the lower PV arrays and blows off the upper PV arrays in the wind.

Yet another feature of the present invention constructed according to this aspect of the invention is that a solar assembly with a curved north-south rail may have a lower vertical height than one with a linear north-south rail having a similar length. This may allow for easier assembly or maintenance on the solar assembly. The reduced vertical height also reduces the size of the shadow cast by the solar assembly and reduces the spacing requirement between rows of solar assemblies in a solar field. This is particularly important because by adding more solar assemblies to a solar field, an increased amount of electricity may be generated in a limited area.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a side view of a known solar assembly;

FIG. 2 is a side view of the first exemplary embodiment of the solar assembly;

FIG. 3 is a perspective view of the first exemplary embodiment of the solar assembly;

FIG. 4 is a table of energy calculation results showing the power produced by a pair of PV panels in a similar geographical location at different orientations for a year;

FIG. 5 is a table of energy calculation results showing the power produced by five different PV panels in a similar geographical location at different orientations for a year;

FIG. 6 is a table of energy calculation results showing the power produced by the known solar assembly of FIG. 1 for a year;

FIG. 7 is a table of energy calculation results showing the power produced by the first exemplary embodiment of the solar assembly for a year;

FIG. 8 is a bar graph showing the results of the tests of FIGS. 6 and 7 in comparative format;

FIG. 9 is a side view of the first exemplary embodiment of the solar assembly and showing air flowing around the solar assembly in a first direction;

FIG. 10 is a side view of the first exemplary embodiment of the solar assembly and showing air flowing around the solar assembly in a second direction opposite of the first direction shown in FIG. 9;

FIG. 11 is a side view of the first exemplary embodiment of the solar assembly and showing the solar assembly's ability to shed snow and ice;

FIG. 12 is a perspective and elevation view of a second exemplary embodiment of the solar assembly;

FIG. 13 is a side view of a pair of solar assemblies of the first exemplary embodiment of the solar assembly arranged in back-to-back relationship;

FIG. 14a is a side view of a solar field including a plurality of the solar assemblies of FIG. 1;

FIG. 14b is a side view of a solar field including a plurality of solar assemblies of FIG. 2; and

FIG. 15 is a chart showing the height, pitch, and annular energy production of various solar assemblies, one of which has a linear north-south rail and the others of which have north-south rails of differing curvatures.

### DETAILED DESCRIPTION OF THE ENABLING EMBODIMENTS

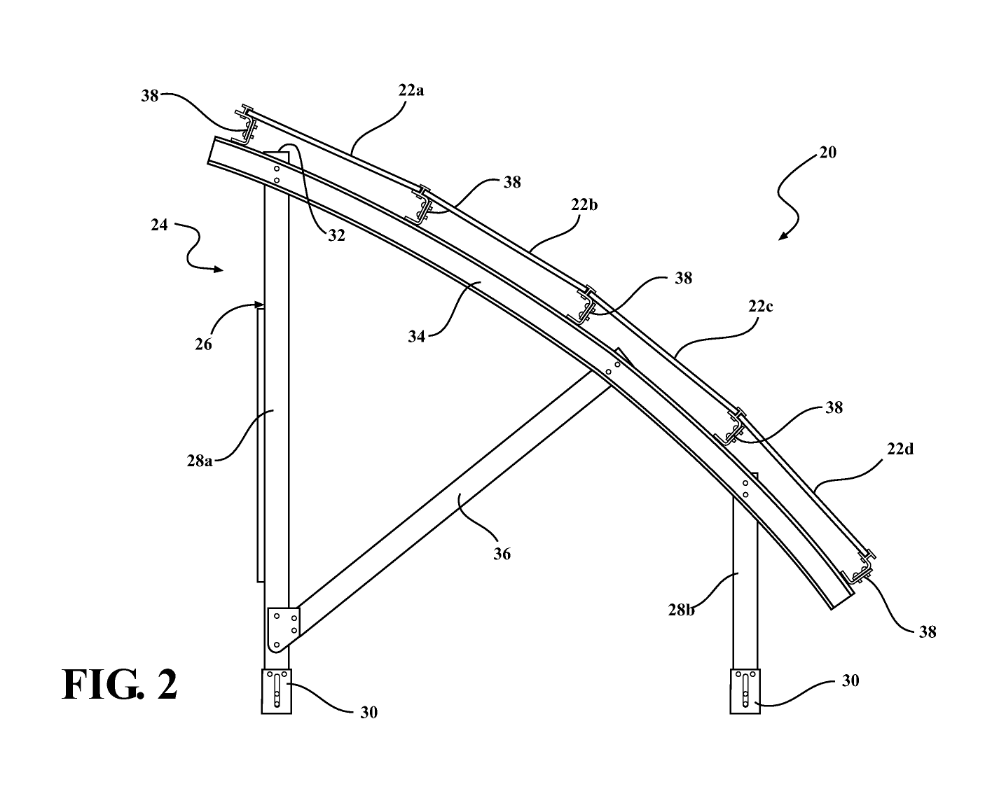

Referring to the Figures, wherein like numerals indicate corresponding parts throughout the several views, a first exemplary embodiment of a solar assembly 20 for harnessing potential energy from solar rays and generating electricity is generally shown in FIG. 2. The solar assembly 20 includes a plurality of solar panels arranged in a plurality of arrays 22a, 22b, 22c, 22d which are supported by a stationary mounting structure 24. In the exemplary embodiment, the solar panels are photovoltaic (PV) cells that are configured to receive solar radiation and convert it into electrical power. However, it should be appreciated that any other type of solar panel capable of converting potential energy from solar rays into electricity or any other form of useable energy could alternately be employed.

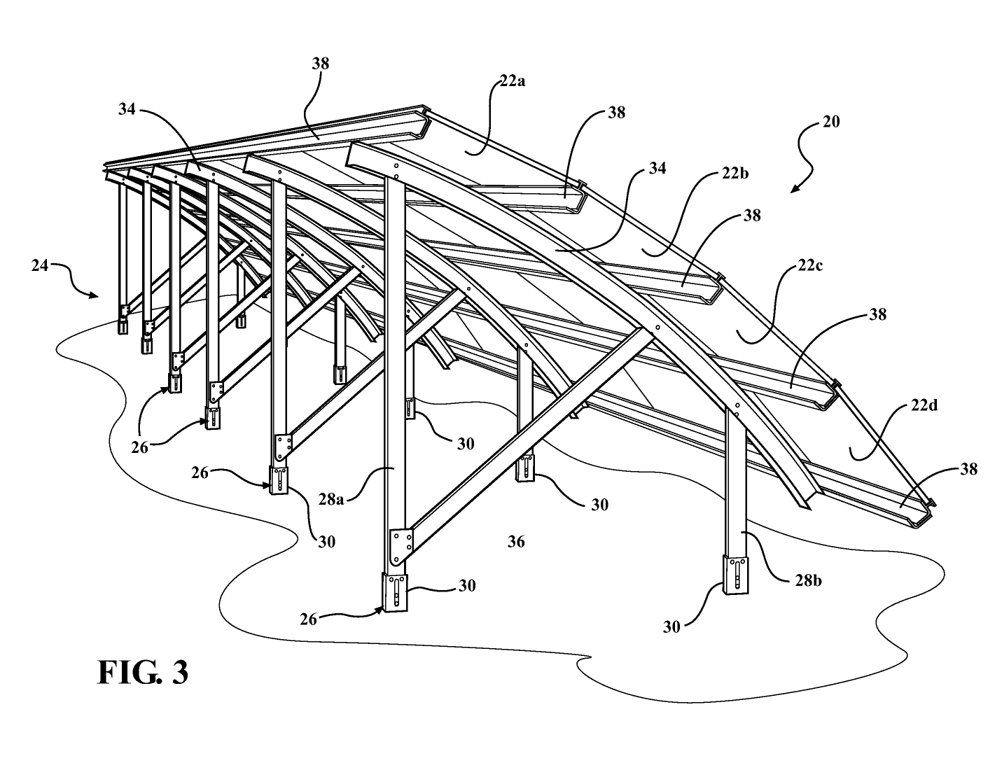

Referring now to FIG. 3, the mounting structure 24 of the first exemplary embodiment includes a plurality of sub-assemblies 26 spaced from one another in a lateral direction, which is hereinafter referred to as an “east-west direction.” Each sub-assembly 26 includes a pair of posts 28a, 28b spaced from one another in a longitudinal direction, which is hereinafter referred to as a “north-south direction”, and each post 28a, 28b extends vertically upwardly from a base attachment point 30 (for attachment to the ground or any other base) to an upper attachment point 32 (shown in FIG. 2). Each sub-assembly 26 also includes a north-south rail 34 (or any other type of member) which is attached to the upper attachment point 32 of the posts 28a, 28b and extends in the north-south direction. As such, the north-south rails 34 of adjacent sub-assemblies 26 extend in generally parallel relationship with one another. For additional support, the sub-assemblies 26 of the first exemplary embodiment also include a strut 36 extending between one of the posts 28a and the north-south rail 34. The mounting structure 24 additionally includes a plurality of east-west rails 38 (or any other type of members) which extend in generally parallel relationship with one another in the east-west direction between the north-south rails 34 of adjacent sub-assemblies 26 to interconnect the sub-assemblies 26. The east-west rails 38 could extend through any length and could interconnect any desirable number of sub-assemblies 26. In the exemplary embodiment, the mounting structure 24 includes five east-west rails 38 which are generally uniformly spaced from one another. Preferably, the posts 28, north-south rails 34 and east-west rails 38 are all formed of metal and shaped through a roll-forming process. However, it should be appreciated that these components could be formed of any suitable material and through any desirable process. The exemplary posts 28a, 28b, north-south rails 36 and east-west rails 38 all have “Lip C” cross-sections. However, it should be appreciated that these components could alternately have tubular, I-shaped, L-shaped, sigma-shaped or any desirable cross-section or cross-sections. It should be noted that the north-south rails 34 and the east-west rails 38 are referred to by the terms “north-south” and “east-west” respectively because this is the normal orientation that they will extend in the field so that the PV arrays 22a, 22b, 22c, 22d face generally south. However, it should be appreciated that they could alternately be oriented in any desirable direction.

Referring back to FIG. 2, all of the PV arrays 22a, 22b, 22c, 22d are generally flat, and as will be discussed in further detail below, adjacent PV arrays 22a, 22b, 22c, 22d are angled relative to one another. The PV arrays 22a, 22b, 22c, 22d are preferably coupled to the east-west rails 38 of the mounting structure 24 through mechanical fasteners. However, it should be appreciated that the PV arrays 22a, 22b, 22c, 22d could alternately be coupled to the east-west rails 38 through any desirable process including, for example, riveting, toggle locs, adhesives, brazing, etc.

The north-south rails 34 of the mounting structure 24 are curved concave downwardly towards the base on which the solar assembly 20 is mounted such that the adjacent arrays 22 (each of which is generally flat) are disposed at different angles relative to the base. As such, an upper-most array 22a is disposed at the shallowest angle relative to the base and the other arrays 22b, 22c, 22d are disposed on one side of the upper-most array 22a at increasingly steeper angles relative to the base.

The curvature of the north-south rail 34 may be selected based at least in part on the latitude of the geographical location where the solar assembly 20 will operate. In other words, modifying the curvature of the north-south rail 34 changes the angles of the PV arrays 22a, 22b, 22c, 22d, which may improve the solar assembly's 20 performance in different geographical locations. For example, it might be preferred to have a lower difference between the angles of the arrays 22a, 22b, 22c, 22d so that the arrays 22a, 22b, 22c, 22d are all disposed at more shallow angles for solar assemblies 20 operating in geographical areas close to the equator, and therefore, north-south rails 34 having a very large radius of curvature might be most desirable for such solar assemblies 20. In contrast, it might be preferred to have a greater difference between the angles of the arrays 22 so that the arrays 22a, 22b, 22c, 22d are disposed at both steep and shallow angles for solar assemblies 20 operating in geographical locations more distant from the equator, and therefore, north-south rails 34 having a smaller radius of curvature might be most desirable. The small radius of curvature allows the PV panels of the upper arrays 22a, 22b (shallow angles) to operate more efficiently in the summer when the sun is higher in the sky and allows the PV panels of the lower arrays 22c, 22d (steep angles) to operate more efficiently in the winter when the sun is lower in the sky. This configuration is also beneficial for shedding snow, as will be discussed in further detail below. The exemplary embodiment was designed for operation in northern Canada, and includes four PV arrays 22a, 22b, 22c, 22d with an eight degree of difference between the angles of adjacent PV arrays 22a, 22b, 22c, 22d. As shown in FIG. 2, the upper-most array 22a is disposed at approximately a twenty-two degree (22°) angle relative to the base for receiving maximum solar rays in the summer, and the lower-most PV array 22d is disposed at approximately a forty-six degree (46°) angle relative to the ground for receiving maximum solar rays in the winter. However, it should be appreciated that the solar assembly 20 could include any number of PV arrays, and those arrays could be disposed at a range of different angles relative to one another and to the base.

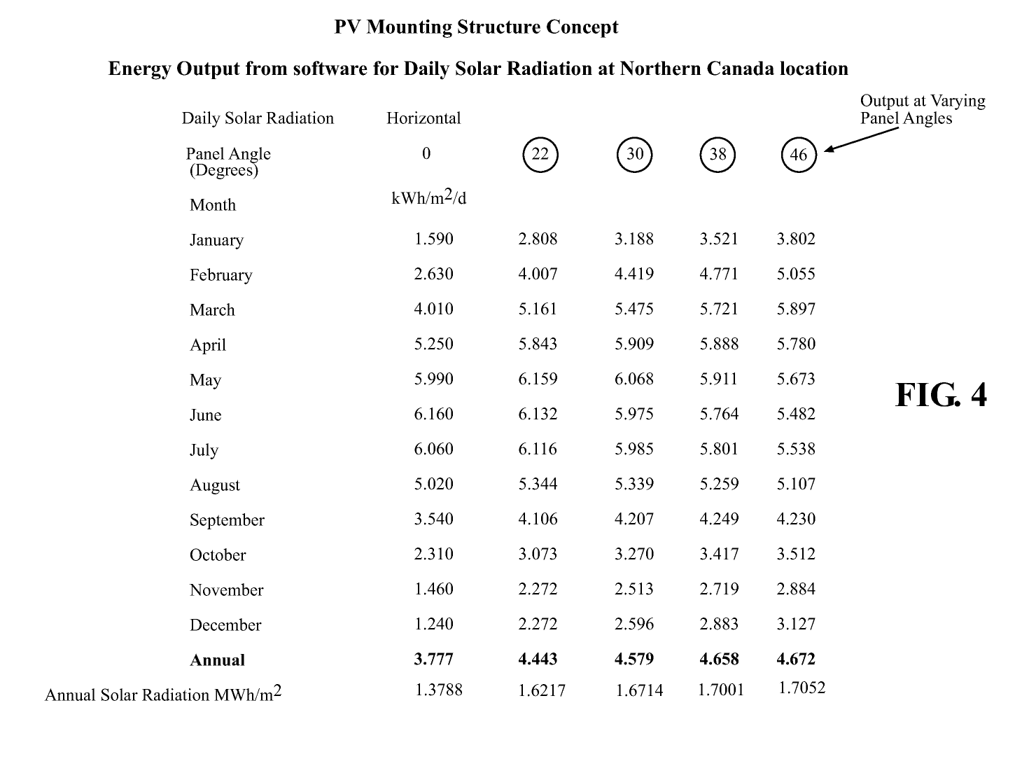

FIG. 4 is a table of energy calculation results showing the power produced by a pair of PV arrays which were operated for a year at a location in northern Canada. One of the PV arrays was oriented at zero degrees (0°), i.e. horizontal, relative to the ground and the other was oriented at twenty-eight degrees (28°) relative to the ground. As can be seen from this table, the inclined PV array produced a comparable amount of power to the horizontal PV array during the summer months and produced significantly more power than the horizontal PV array during the fall, winter, and spring months. This table demonstrates the value of angling the PV arrays to maximize their power output.

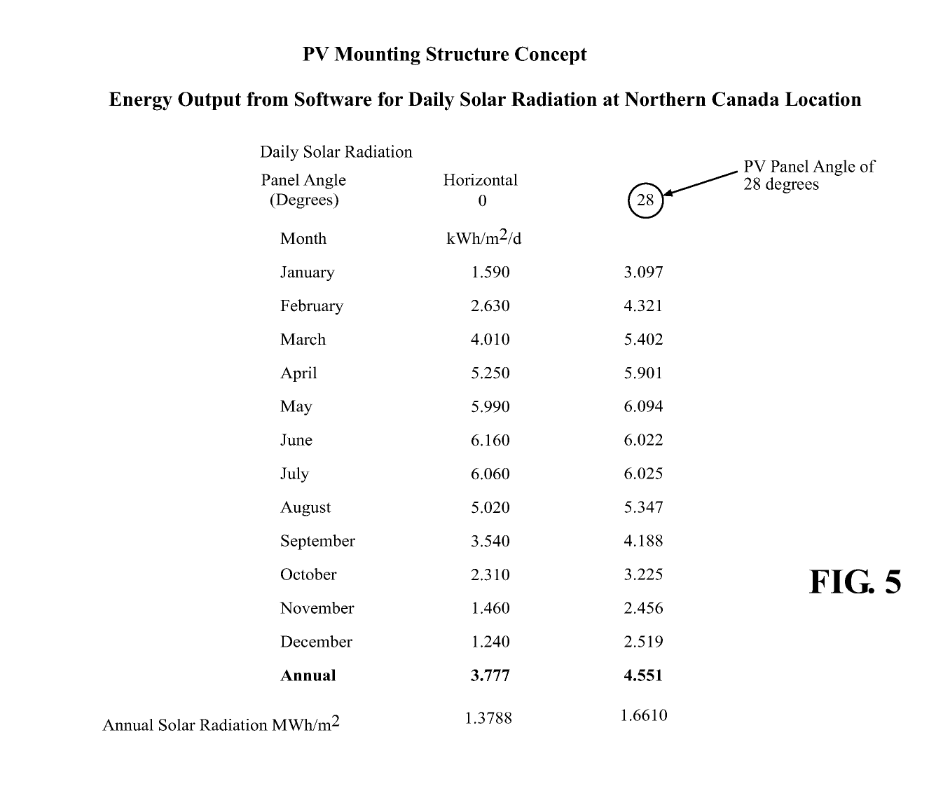

FIG. 5 is a table of energy calculation results showing the power produced by five PV arrays which were also operated for a year at a location in northern Canada. As can be seen from this table, the less inclined PV arrays produced the most power output during the summer months and the more inclined PV arrays produced the most power in the winter months. This table demonstrates the value of having a PV array with both less inclined and more inclined PV arrays to reduce the difference in power produced by the solar assembly between the summer and winter months and to thereby increase the total power produced annually.

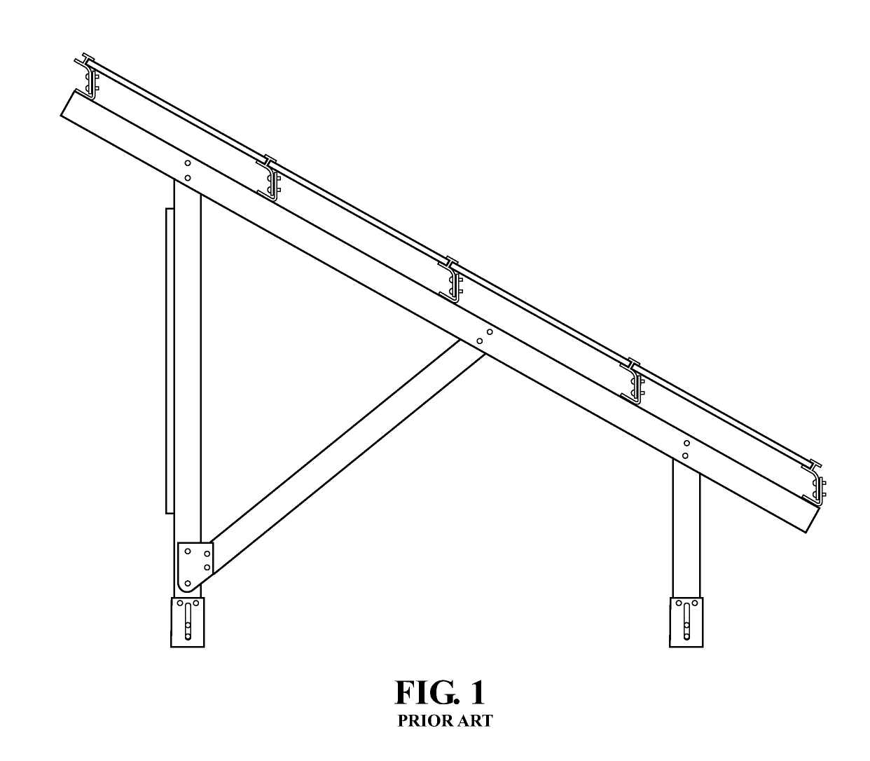

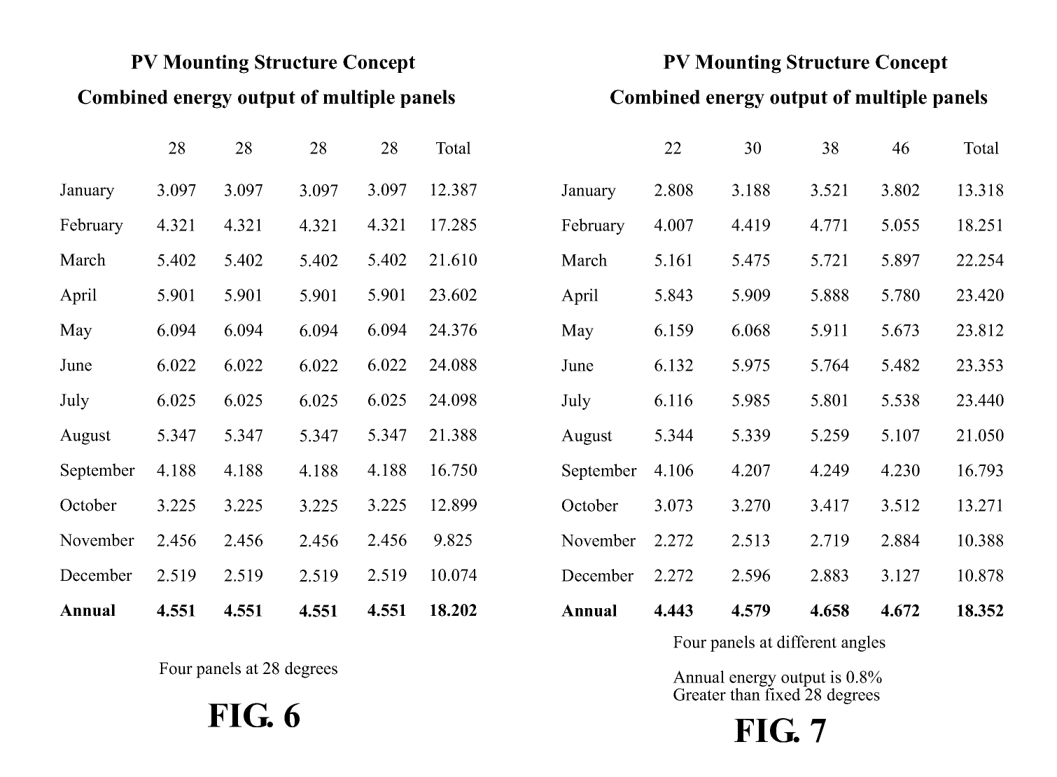

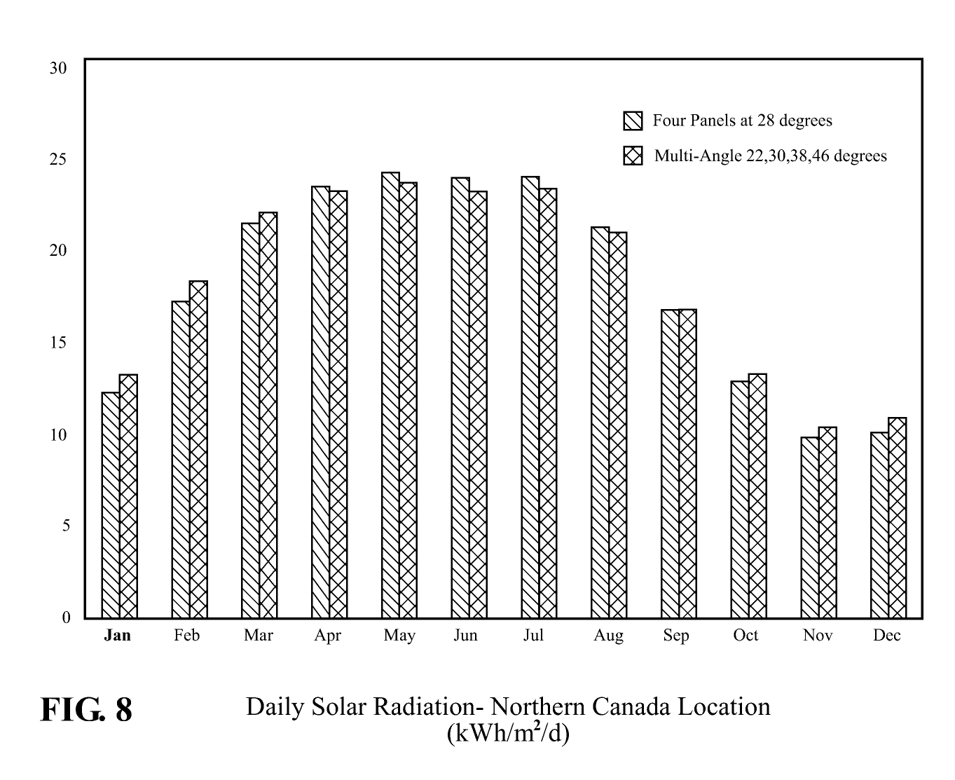

FIG. 6 is a table of energy calculation results showing the power produced over the course of a year by a known solar assembly, such as the one shown in FIG. 1, with a linear north-south rail and including four PV arrays, all oriented at a twenty-eight degree (28°) angle relative to the ground. In contrast, FIG. 7 is a table showing the power produced over the course of a year by the first exemplary solar assembly 20 shown in FIG. 2 including a curved north-south rail 34 and four solar arrays 22a, 22b, 22c, 22d oriented at 22°, 30°, 38° and 46° inclines. These energy calculation results of FIGS. 6 and 7 are also illustrated in graphical format in FIG. 8. As can be seen, the solar assembly 20 with the curved north-south rail 34 produced 0.8% more energy throughout the year than the solar assembly 20 of FIG. 1. Therefore, the first exemplary solar assembly 20 is more efficient in at least this geographical location than the known solar assembly of FIG. 1. Even further, the results demonstrate that the first exemplary solar assembly 20 produced significantly more power during the winter months than the known solar assembly 20 of FIG. 1, thus reducing the need for a supplemental energy source during these months.

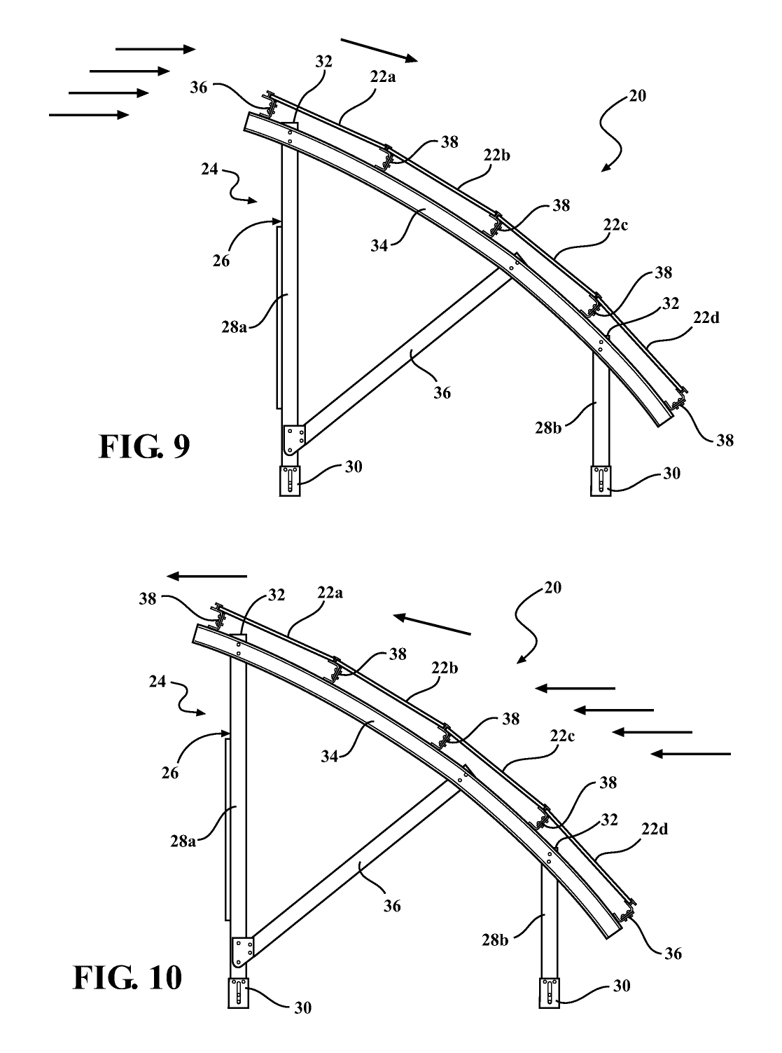

Referring now to FIGS. 9 and 10, the curvature on the north-south rails 34 provides additional strength and aerodynamic advantages as compared to comparable linear north-south rails 34. For example, the curved, or arched, design is inherently stronger than a linear design, thereby allowing the various components of the mounting structure 24 to be formed of lighter and less costly materials with no loss in strength. Additionally, the first exemplary solar assembly 20 is more aerodynamic than the solar assembly of FIG. 1 regardless of whether wind is approaching the solar assembly 20 from a first direction, as shown in FIG. 9 with arrows indicating air flow or a second direction opposite of the first direction as shown in FIG. 10 with arrows indicating air flow. In other words, the shape of the first exemplary solar assembly 20 provides for improved aerodynamic flow, which reduces the magnitude of forces exerted on the mounting structure 24 during windy conditions. As such, the mounting structure 24 may be formed of lighter, cheaper materials without compromising its ability to withstand wind forces in the outdoor environment in which it operates. Although not shown in the Figures, an aerodynamic fairing (i.e. wind foil) may be added to the top of the mounting structure 24 to bring the angle of the top of the solar assembly 20 to the horizontal and further improve the aerodynamics of the solar assembly 20. This could also be achieved by modifying the mounting structure 24 to accommodate additional PV arrays at further reduced angles to bring the angle of the top of the solar assembly 20 to horizontal.

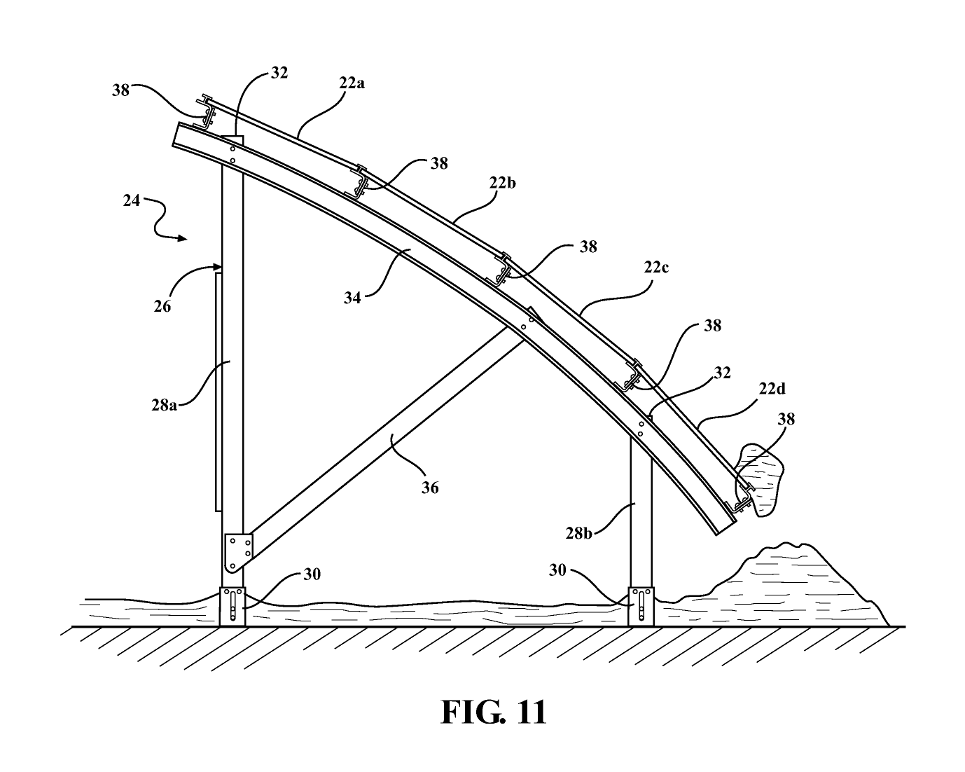

Yet another benefit of the curved north-south rail 34 is the solar assembly's 20 ability to shed snow, ice, hail, or rain which could otherwise partially or totally block solar rays from encountering the solar arrays 22a, 22b, 22c, 22d. Specifically, as shown in FIG. 11, the steep angles of the lower solar arrays 22c, 22d (which are most effective during the winter when the sun is at a lower angle in the sky) automatically shed such precipitation. Likewise, wind may blow off any snow on the upper arrays 22a, 22b, which are oriented at a shallow angle relative to the base. In the solar assembly 20 of FIG. 1, the shedding ability may only be increased by increasing the angle of the linear north-south rail 34 but that will come at a consequence to the solar assembly's 20 ability to receive sunlight in the summer months when the sun is at a steeper angle in the sky.

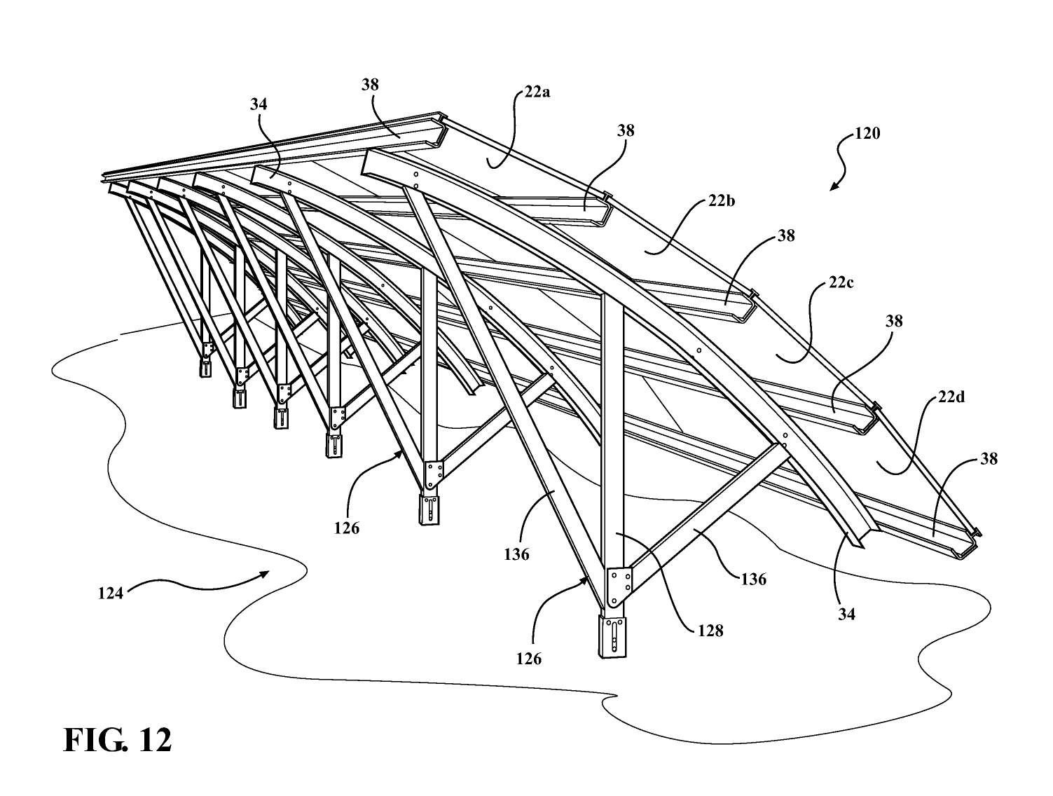

A second exemplary mounting structure 124 is generally shown in FIG. 12. The second exemplary mounting structure 124 is similar to the first exemplary embodiment discussed above except that it includes a single post 128 and two struts 136 rather than two posts 28 and a single strut 36. As discussed above, it should be appreciated that the mounting structure could take a number of different shapes and designs other than those shown in the exemplary embodiments.

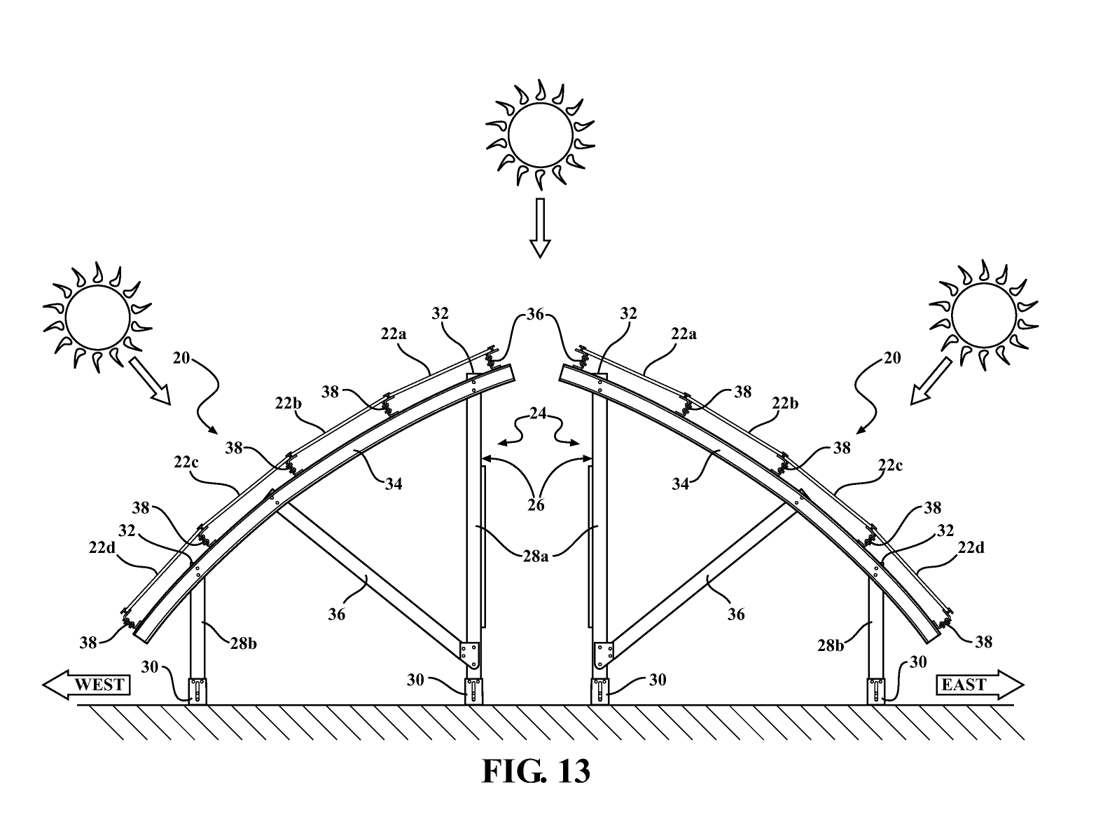

Referring now to FIG. 13, two solar assemblies 20 are positioned adjacent one another and arranged in back-to-back (or mirrored) relationship with one another with the arrays 22a, 22b, 22c, 22d of one solar assembly 20 facing west and the arrays 22a, 22b, 22c, 22d of the other solar assembly 20 facing east. This orientation may be advantageous since it provides aerodynamic advantages for both solar assemblies 20 by reducing turbulence and also results in increased sun exposure during the day. Specifically, the arrays 22a, 22b, 22c, 22d of the solar assembly 20 that faces east receive an increased amount of sunlight during the morning and the arrays 22a, 22b, 22c, 22d of the solar assembly 20 facing west receive an increased amount of sunlight during the evening. As such, in this layout, the north-south rails 34 are actually oriented in an east-west direction and the east-west rails 38 are actually oriented in a north-south direction. Even further, it should be appreciated that the back-to-back solar assemblies 20 shown in FIG. 13 could be combined into one unified structure with a generally arcuate shape.

The mounting structure 24, 124 could be produced using any desirable manufacturing method. For example, the curved north-south rail 34 could be roll-formed, brake pressed, extruded, stamped, machined, or shaped using any other desirable forming process. The north-south rails 34 could have any desirable profiles or profiles (i.e. cross-section or cross-sections) including, for example, a C-shape, Lip C shape, hat shape, tube shape, I-beam shape, sigma shape, etc. The components of the mounting structure 24, 124 may additionally be constructed with slots for allowing slip-planes for in-field adjustment of the solar assembly 20, 120. Preferably, the north-south rail 34 is given its curvature through a roll-forming process. As such, with small modifications to the roll-forming equipment, north-south rails 34 having different curvatures can be produced. The posts 28a, 28b, struts 36, and east-west rails 38 may all be used with north-south rails 34 of various curvatures. As such, with very small changes to the manufacturing equipment, solar assemblies that are optimized for different geographic locations may be produced. With this flexibility comes certain manufacturing and advantages and cost savings.

Additionally, the north-south rails 34 could have a constant curvature, a variable curvature or a partial curvature with straight sections. In other words, the north-south rails 34 could extend through a generally constant sweep with a generally constant radius of curvature as shown in the Figures) or the curvature could change along its length. For example, the north-south rail 34 could have a one or more curves with generally straight sections disposed adjacent or between the curves.

In the exemplary embodiments discussed above the PV panels are arranged in a landscape orientation in the PV arrays 22a, 22b, 22c, 22d. However, it should be appreciated that the PV panels could alternately be arranged in a portrait orientation though this may require additional east-west rails 34. Additionally, the solar assembly 20, 120 could include any desirable number of PV arrays.

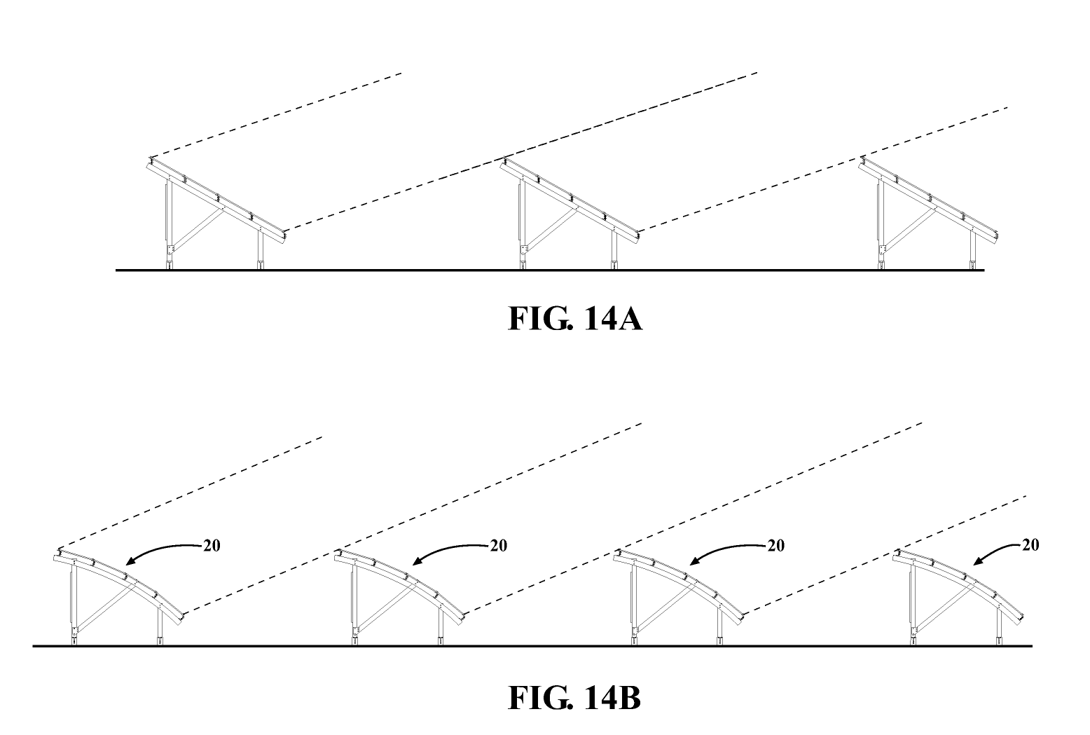

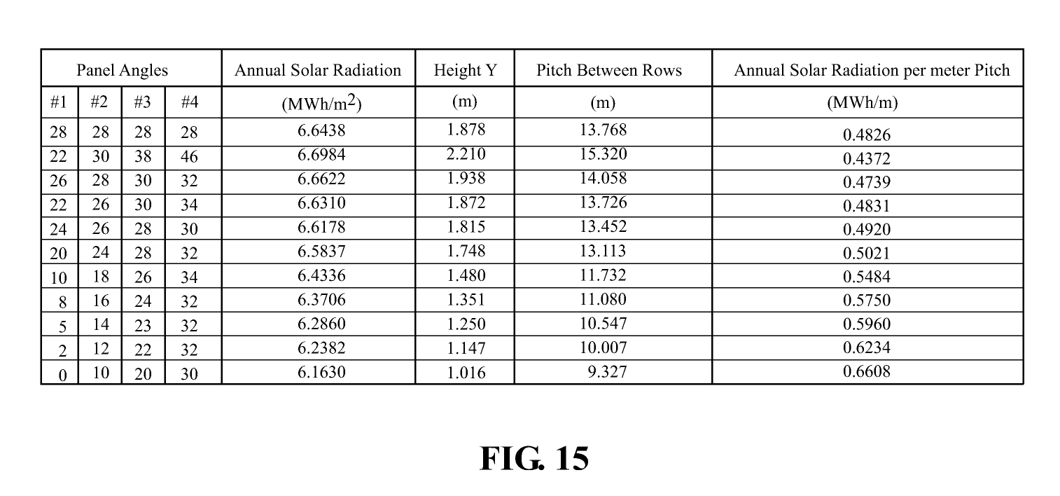

Referring now to FIGS. 14a and 14b, yet another feature of the first exemplary solar assembly 20 is that it has a lower vertical height than a solar assembly with a linear north-south rail having a similar length. This may allow for easier assembly or maintenance on the solar assembly 20. Additionally, the reduced vertical height also reduces the size of the shadow cast by the solar assembly 20 and reduces the spacing requirement between rows of solar assemblies 20 in a solar field. This is particularly important because by adding more solar assemblies 20 to a solar field, an increased amount of electricity may be generated in a limited area. In other words, the total number of PV arrays 22a, 22b, 22c, 22d which receive exposure from the sun in a predetermined area may be increased to increase the total power produced by the solar field.

Obviously, many modifications and variations of the present invention are possible in light of the above teachings and may be practiced otherwise than as specifically described while within the scope of the appended claims.

1. A solar assembly for harnessing solar rays and generating electricity, comprising:
at least two posts extending vertically upwardly from a base and spaced from one another;
at least two north-south rails, each being coupled to an upper end of one of said posts and extending in generally parallel relationship with one another;
at least two east-west rails coupled to and extending between said north-south rails and extending in generally spaced and parallel relationship with one another;
a plurality of generally flat arrays of solar panels coupled to said east-west rails; and
wherein said at least two north-south rails are curved concavely downwardly such that at least one of said arrays is oriented at a different angle relative to the base than another of said arrays.

2. The solar assembly as set forth in claim 1 wherein said plurality of arrays includes an upper-most array and the other of said arrays are positioned on one side of said upper-most array and are oriented at increasingly steeper angles relative to said upper-most array.

3. The solar assembly as set forth in claim 2 wherein said upper-most array is disposed at an angle of less than twenty-five degrees relative to the base and wherein a lower-most of the arrays is disposed at an angle of greater than forty degrees relative to the base.

4. A solar assembly for harnessing solar rays and generating electricity, comprising:
at least two posts spaced from one another in a lateral direction with each post extending in a vertical direction from a base attachment point to an upper attachment point;
at least two lateral members extending in a lateral direction with one of said lateral members being coupled to said upper attachment point of each post;
a plurality of longitudinal members coupled to and extending between said lateral members with said lateral members being spaced from one another in said longitudinal direction;
a plurality of generally flat solar panels coupled to said longitudinal members; and
wherein said lateral members are curved concavely downwardly towards said base attachment points of said posts such that at least two of said generally flat solar panels are oriented at different angles than one another.

5. The solar assembly as set forth in claim 4 wherein said generally flat solar panels are arranged in a plurality of arrays and wherein said arrays are coupled to said longitudinal members such that each array is disposed at a different angle relative to a base than the other arrays.

6. The solar assembly as set forth in claim 5 wherein said plurality of arrays includes an upper-most array and wherein the other arrays are disposed on one said of said upper-most array and are oriented at increasingly steeper angles relative to said upper-most array and to the base.

7. The solar assembly as set forth in claim 6 wherein each array is substantially oriented at an angle of greater than zero degrees relative to each adjacent array.

8. The solar assembly as set forth in claim 7 wherein said solar panels are oriented in either a portrait or a landscape orientation in each of said arrays.

9. The solar assembly as set forth in claim 5 wherein said plurality of arrays is further defined as at least two arrays.

10. The solar assembly as set forth in claim 9 wherein said at least two longitudinal members is further defined as at least three longitudinal members spaced from one another long the lengths of said concave lateral members.

11. The solar assembly as set forth in claim 5 wherein said plurality of arrays includes an upper-most array and a lower-most array and wherein said lower-most array is raised above the base.

12. The solar assembly as set forth in claim 4 wherein each of said lateral members is supported by at least two posts.

13. The solar assembly as set forth in claim 12 further including a strut extending from one of said posts to one of said lateral members for providing additional support to the associated lateral members.

14. The solar assembly as set forth in claim 4 wherein said generally flat solar panels are photovoltaic panels.

15. An assembly for harnessing solar rays and generating electricity, comprising:
a pair of solar assemblies;
each solar assembly including at least two posts spaced form one another in a lateral direction, at least two lateral members extending in a lateral direction, a plurality of longitudinal members coupled to and extending in a longitudinal direction between said lateral members, and a plurality of generally flat solar panels coupled to said longitudinal members;
wherein said lateral members are curved concave downwardly such that at least two of said generally flat solar panels are oriented at different angles than one another; and
wherein said solar assemblies are positioned adjacent one another and are arranged in mirrored relationship with one another.
